(19) United States
(12) Patent Application Publication
(10) Pub. No.: US 2019/0348138 A1
(43) Pub. Date: Nov. 14, 2019

(54) TEST MODE SIGNAL DISTRIBUTION SCHEMES FOR MEMORY SYSTEMS AND ASSOCIATED METHODS

(71) Applicant: Micron Technology, Inc., Boise, ID (US)

(72) Inventors: Christian N. Mohr, Allen, TX (US); Scott E. Smith, Plano, TX (US)

(21) Appl. No.: 15/977,959

(22) Filed: May 11, 2018

(51) Int. Cl. G11C 29/14; G11C 11/4093; G11C 7/10; G11C 29/18

(52) U.S. Cl. CPC G11C 29/14; G11C 29/18; G11C 7/1006; G11C 11/4093

(57) ABSTRACT

In a particular embodiment, a method of operating a memory device includes assigning a plurality of signals to a group and multiplexing the group of assigned signals onto a data transmission line. Each of the multiplexed signals can be individually demultiplexed by locally latching individual signals at corresponding target destinations. Demultiplexing each of the signals can be based on a phase signal received at the target destination and that includes the group which the corresponding individual signal was assigned to.

### TECHNICAL FIELD

The present disclosure relates generally to semiconductor devices, and more particularly relates to test mode signal distribution schemes for semiconductor systems and associated methods,

### BACKGROUND

Memory devices are widely used to store information related to various electronic devices such as computers, wireless communication devices, cameras, digital displays, and the like. Memory devices are frequently provided as internal, semiconductor, integrated circuits and/or external removable devices in computers or other electronic devices. There are many different types of memory, including volatile and non-volatile memory. Volatile memory, including random-access memory (RAM), static random access memory (SRAM), dynamic random access memory (DRAM), and synchronous dynamic random access memory (SDRAM), among others, may require a source of applied power to maintain its data. Non-volatile memory, by contrast, can retain its stored data even when not externally powered. Non-volatile memory is available in a wide variety of technologies, including flash memory (e.g., NAND and NOR), phase change memory (PCM), ferroelectric random access memory (FeRAM), resistive random access memory (RRAM), and magnetic random access memory (MRAM), among others. Improving memory devices, generally, may include increasing memory cell density, increasing read/write speeds or otherwise reducing operational latency, increasing reliability, increasing data retention, reducing power consumption, or reducing manufacturing costs, among other metrics.

Chip makers often include test mode functions on such memory devices to improve the productivity, quality and yield of the memory device as well as configure the part type, Test modes are often needed to affect circuit blocks of the chip, including data I/O and controls, memory cell array and controls, address and command inputs and controls, etc. Routes associated with these test modes need to reach a large number of circuit blocks, frequently requiring chips to have several hundred global routes if not more. Over time, the need for test mode functions has steadily increased as memory chips have become more advanced, which has caused routes associated with test modes to occupy more space on the chip. As such, test mode routing has negatively impacted layout efficiency by increasing chip size.

### BRIEF DESCRIPTION OF THE DRAWINGS

FIG. 1 is a simplified block diagram schematically illustrating a memory device in accordance with embodiments of the present technology.

FIG. 2 is a simplified block diagram schematically illustrating a memory device in accordance with embodiments of the present technology.

FIG. 3 is a simplified timing diagram schematically illustrating operations of a memory device in accordance with embodiments of the present technology.

FIG. 4 is a flow chart illustrating a method of operating a memory device in accordance with embodiments of the present technology.

FIG. 5 is a schematic view of a system that includes a memory device configured in accordance with embodiments of the present technology.

### DETAILED DESCRIPTION

Memory devices and systems associated with such devices can include a plurality of test modes (“TMs”) which are often needed to affect circuit blocks of the chip, including data I/O and controls, memory cell array and controls, address and command inputs and controls, etc. The TMs can be used to, e.g., trim critical timings associated with functionality of a chip, stress the device to discover defects, and/or configure the part type. In conventional or traditional memory devices, each TM signal and its corresponding TM bits are latched in a singular location and then distributed on an individual data transmission line to its destination, where the TM bit controls the destination local logic. Because hundreds of TM signals are sent to different circuits on a chip, the test mode distribution scheme of conventional devices can require hundreds of transmission lines and cause bottlenecks to arise that reduce the overall performance of the device.

The present technology disclosed herein is an improved distribution scheme for sending and receiving signals to their corresponding target destinations. In some embodiments of the present technology, for example, a method of operating a memory device or system includes multiplexing (e.g., time multiplexing) a plurality of signals having test mode data onto a single data transmission line and then individually demultiplexing (e.g., latching) each of the signals at their corresponding target destinations.. Demultiplexing each of the signals can be based at least in part on a phase signal (e.g., a phase timing signal) received at local latches at the target destinations of each of the corresponding signals. As explained in further detail below, such a distribution scheme can reduce the number of transmission lines needed on a chip, thereby reducing or even eliminating layout bottlenecks and improving overall performance of the memory device or system.

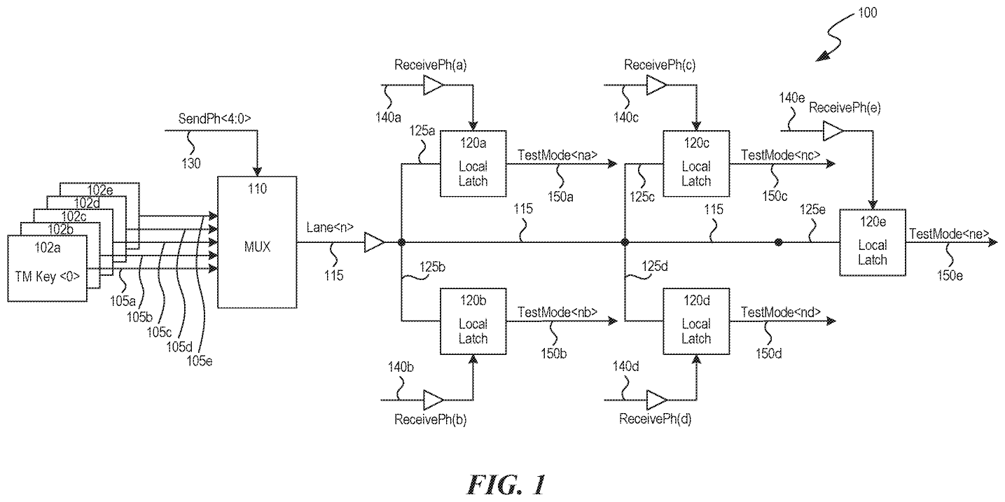

FIG. 1 is a simplified block diagram schematically illustrating the operation of a memory device 100 (“device 100”) in accordance with embodiments of the present technology. The memory device 100 can be connected to any one of a number of electronic devices capable of utilizing memory for the temporary or persistent storage of information, or a component thereof. For example, a host device of memory device 100 may be a computing device such as a desktop or portable computer, a server, a hand-held device (e.g., a mobile phone, a tablet, a digital reader, a digital media player), or some component thereof (e.g., a central processing unit, a co-processor, a dedicated memory controller, etc.). The host device may be a networking device (e.g., a switch, a router, etc.) or a recorder of digital images, audio and/or video, a vehicle, an appliance, a toy, or any one of a number of other products. In one embodiment, the host device may be connected directly to the memory device 100, although in other embodiments, the host device may be indirectly connected to memory device (e.g., over a networked connection or through intermediary devices).

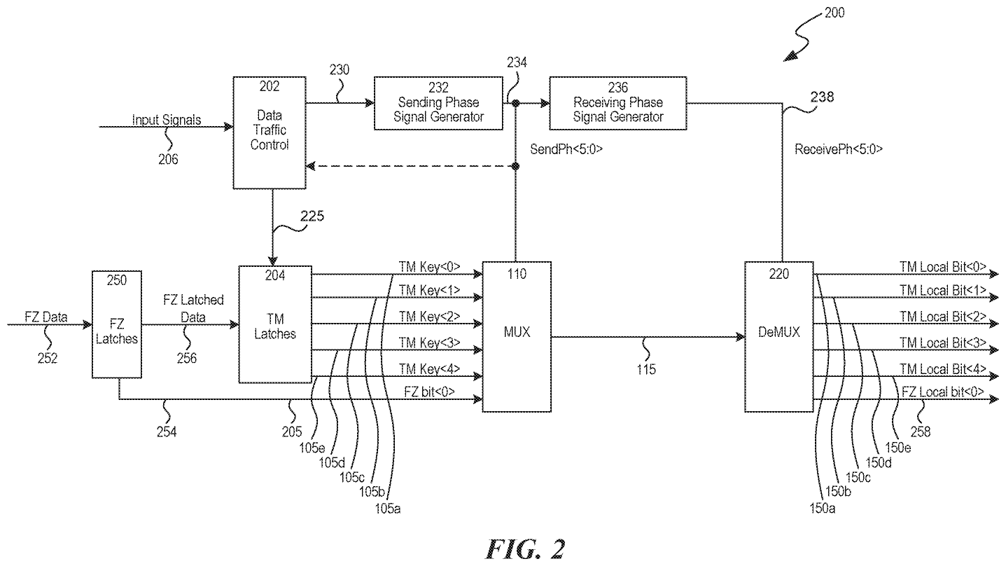

As shown in the illustrated embodiment, the device 100 includes a plurality of TM signals 105a-e (collectively referred to as “TM signals 105”), and a multiplexer 110 configured to receive the TM signals 105 and multiplex (e.g., time multiplex) them onto one or more of a plurality of global data transmission lines (“lanes”). As shown in the illustrated embodiment, the TM signals 105 are multiplexed onto a lane 115 (shown as “Lane<n>”). Though only a single lane is shown in the illustrated embodiment, lane 115 represents one of a plurality of lanes onto which the TM signals 105 can be sent. The TM signals 105 can each include TM data (e.g., TM bits or TM keys such as 102a, 102b, 102c, 102d, 102e) corresponding to a target destination. Furthermore, the TM signals 105 can include other data, such as fuse data, to be sent along with the TM data to the corresponding target destinations. As explained in additional detail below with reference to FIG. 2, each of the TM signals 105 can also include or be assigned an address that corresponds to its target destination. Prior to multiplexing the TM signals 105 onto the lane 115, a sending phase signal 130 (shown as “SendPh<4:0>”) is received by the multiplexer 110. The sending phase signal 130 is a timing signal that is assigned to each group of TM signals 105. In some embodiments, the sending phase signal is determined based on an address associated with the group of TM signals 105. The group to which a signal is assigned can be based on, e.g., the target destination of that signal, with signals having a similar (e.g., topologically close) or same destination being assigned to the same group. Once the sending phase signal 130 is received by the multiplexer 110, all of the members of that group are multiplexed onto the lane 115.

After the TM signals 105 are multiplexed onto the lane 115, each signal is demultiplexed (e.g., locally latched) at its corresponding target destination. As shown in the illustrated embodiment, the TM signals 105 reach their target destination via individual local transmission lines 125a, 125b, 125c, 125d, 125e (collectively referred to as “local lines 125”), each of which branches off of the lane 115. Each of the TM signals 105 is latched at its corresponding target destination via one of local latches 120a, 120b, 120c, 120d, 120e (collectively referred to as “local latches 120”). Latching the individual TM signals 105 at their corresponding local latches 120 can be based on corresponding receiving phase signals 140a, 140b, 140c, 140d, 140e (collectively referred to as “receiving phase signals 140”) received by the individual local latches 120. The receiving phase signals 140 are timing signals that correspond to the sending phase signal 130, and provide notification to the corresponding local latches 120 of the lane on which a particular TM signal has been sent and of the group to which a particular TM signal has been assigned. Locally latching the TM signals at the local latches 120 results in each of the output TM signals 150a, 150b, 150c, 150d, 150e (collectively referred to as “TM signals 150”) being received only at the corresponding target destination.

As shown in the illustrated embodiment, local line 125a branches off of the lane 115 and routes TM signal 105a to local latch 120a. The local latch 120a receives a receiving phase signal 140a (shown as “ReceivePh(a)”) which corresponds to the sending phase signal 130 sent prior to the TM signal 105a being multiplexed. The receiving phase signal 140a is used to select local latch 120a at the target destination for the corresponding signal. To minimize the routing length, the individual local latches 120 are placed in close proximity to their corresponding destination control logic. Once the TM signal 105a reaches the local latch 120a (i.e., its target destination), the TM signal 105a can be locally latched and the test mode signal 150a (shown as “TestMode<na>”) can be executed. As further shown in the illustrated embodiment, a similar procedure is performed for each of the other TM signals 105b, 105c, 105d, 105e. For example, (a) TM signal 105b travels along local line 125b to local latch 120b which receives a receiving phase signal 140b (shown as “ReceivePh(b)”) and locally latches the TM signal 105b, (b) TM signal 105c travels along local line 125c to local latch 120c which receives a receiving phase signal 140c (shown as “ReceivePh(c)”) and locally latches the TM signal 105c, (c) TM signal 105d travels along local line 125d to local latch 120d which receives a receiving phase signal 140d (shown as “ReceivePh(d)”) and locally latches the TM signal 105d, and (d) TM signal 105e travels along local line 125e to local latch 120e which receives a receiving phase signal 140e (shown as “ReceivePh(e)”) and locally latches the TM signal 105e,

Embodiments of the memory system 100 and distribution scheme described above can have a number of advantages over conventional or traditional technologies, such as those described above. For example, traditional data distribution schemes loaded each TM signal from single, local location, and then individually routed each signal directly to its destination on a data transmission line. This distribution scheme required a large number of data transmission lines and significant time to send all of the TM signals to their target destinations. The present technology addresses the challenges of conventional technologies by providing the ability to send multiple TM signals onto a single data transmission line. As such, embodiments of the present technology can significantly decrease the number of data transmission lines needed to route each TM signal to its corresponding target destination or circuit. In turn, embodiments of the present technology can free up space previously occupied by data transmission lines to be used for other desired circuits or to decrease the size of a chip.

FIG. 2 is a simplified block diagram schematically illustrating a memory device 200 (“device 200”) in accordance with embodiments of the present technology. As shown in the illustrated embodiment, many of the features described above with reference to FIG. 1 are also represented in FIG. 2. For example, input TM signals 105 are multiplexed via multiplexer 110 onto the lane 115, and are demultiplexed at their corresponding local target destinations into corresponding output TM signals 150. As shown in the illustrated embodiment, demultiplexer 220 schematically represents each of the local latches 120 referred to in FIG. 1. As described above with reference to FIG. 1, each of the input TM signals 105 and corresponding output TM signals 150 can include TM keys (e.g., shown as TM Key<0>, TM Key<1>, TM Key<2>, TM Key<3>, TM Key<4>) or TM bits (e.g., shown as TM Local Bit <0>, TM Local Bit TM Local Bit <2>, TM Local Bit <3>, TM Local Bit <4>).

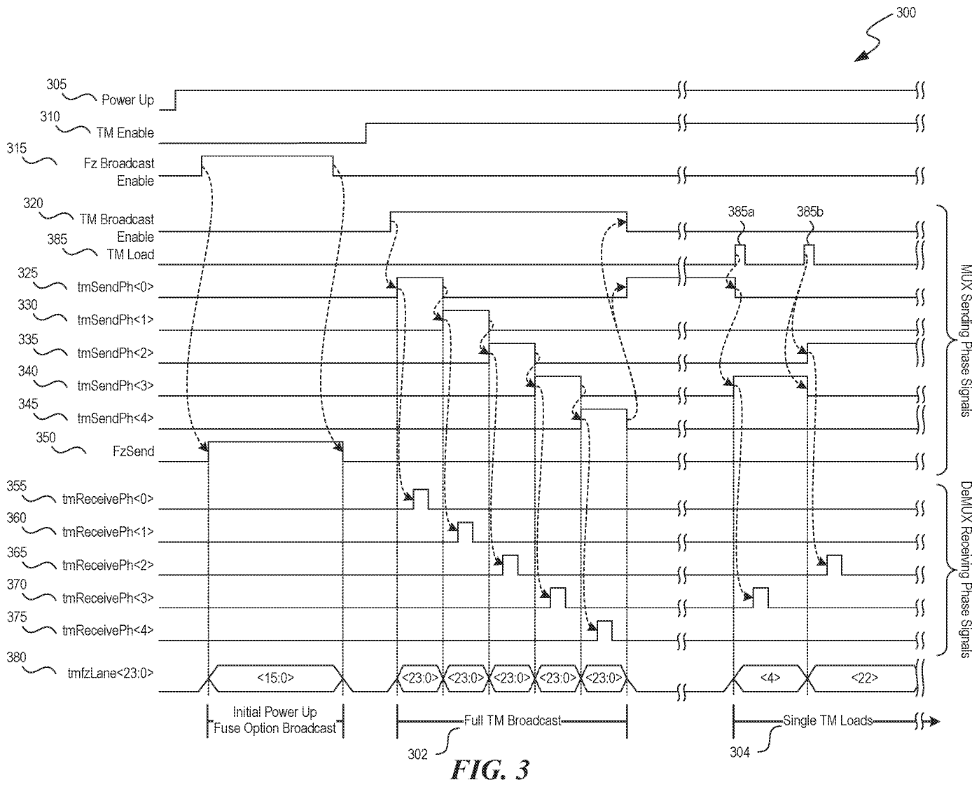

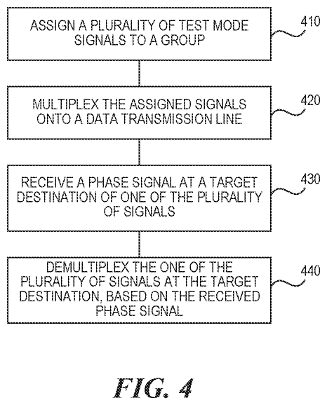

The memory device 200 further includes a data traffic control block 202 (“control block 202”) for routing TM bits to their appropriate target destinations, and a TM latches block 204 for storing TM bits prior to being multiplexed. The control block 202 includes control logic configured to control the traffic traveling on the lane 115. Though only a single lane is shown, the lane 115 is part of a data transmission bus that includes a plurality of lanes (e.g., 2-30 lanes), which define a width of the bus. The control logic block 202 receives input signals 206 used to designate which TM bits or keys are to be sent or broadcasted (e.g., via a broadcast enable signal) to their target destination, and can assign addresses to those TM bits or keys to ensure they are sent appropriately. For example, in a particular embodiment, the control logic can assign each test key or bit of a TM signal to a particular group or phase, and can cause the group, and each of the assigned test keys or bits contained therein, to be routed onto a particular lane (e.g., lane 115). Furthermore, the control logic can generate phase signals (e.g., sending phase signal 130 and receiving phase signals 140 described above with reference to FIG. 1 and in additional detail below with reference to FIGS. 3 and 4) to ensure each TM bit or key is routed to and received at its corresponding target destination. The TM bits or keys to be multiplexed are sent from the control block 202 to the TM latches block 204 via a signal 225, which can include, e.g., the addresses corresponding to the target destinations for each of the TM bits or keys.

In some embodiments, the input signals 206 can include a clearing signal configured to clear (e.g., reset) the current state local latches (represented schematically by demultiplexer 220). The clearing function can be caused by a clearing signal including a device initialization signal (e.g., TM Broadcast Enable signal, as describe below with reference to FIG. 3) or a TM Clear signal. In such embodiments, upon receiving the clearing signal, the local latches can be set or reset to a known default state. After being set or reset , individual local latches can then be changed from the default state to a different state based on, e.g., individual receiving phase signals (e.g., receiving phase signal 238, as described below with reference to FIG. 2).

As shown in the illustrated embodiment, the control logic generates an output signal 230 to a sending phase signal generator 232. The output signal 230 can include information corresponding to which TM signals 105 are to be sent next via multiplexer 110 to their corresponding target destinations. As described in further detail with reference to FIG. 3, the output signal 230 can be a broadcast enabling signal for a plurality of phases or groups of signals, or can be a TM load signal for a single phase or group of signals. In some embodiments, the output signal 230 can include information corresponding to the group or phase to which the TM signals 105 are to be assigned. In other embodiments, the sending phase signal generator 232 can determine to which group or phase the TM signals 105 are to be assigned. The sending phase signal generator 232 generates a sending phase signal 234 (shown as “SendPh<5:0>”) that incorporates, e.g., the group or phase to which the TM signals 105 are to be assigned, the addresses of the target destinations of the individual TM signals 105, and/or the lane onto which the group is to be multiplexed. As shown in the illustrated embodiment, the sending phase signal 234 is sent to a receiving phase signal generator 236 and the multiplexer 110. In some embodiments, the sending phase signal 234 can also be sent to the control block 202. The sending phase signal 234 sent to the multiplexer can initiate the multiplexer 110 to multiplex the TM signals 105 onto the lane 115. The sending phase signal 234 received by the receiving phase signal generator 236 can cause the receiving phase signal generator 236 to send receiving phase signals 238 (represented by a single line) to each of the target destinations for the corresponding TM signals that have been or are to be multiplexed. Stated differently, a receiving phase signal is sent to each local latch (e.g., local latches 120 referenced in FIG. 1) where the individual TM signals are to demultiplexed. As explained in detail with reference to FIG. 3, the sending phase signal generator 232 and/or the receiving phase signal generator 236 can include delay logic to ensure the device 200 operates effectively. In some embodiments, for example, the delay logic is used to ensure a first sending phase signal corresponding to a first group does not overlap with a second sending phase signal corresponding to a second group sent on the same lane as the first group. Delay logic of the sending phase signal generator 232 can also be used to delay the time the receiving phase signal 238 is sent until a set amount of time (e.g., a predetermined time) after the sending phase signal 234 is sent. Since the sending phase signal 234 indicates that the TM data for that particular group or phase have been multiplexed and sent onto the lane 115, delaying the initiation of the receiving phase signal can help ensure that the receiving phase signal is sent after the TM data has been sent.

As further shown in the illustrated embodiment, memory device 200 further includes a fuse latching block 250 that receives fuse data 252 to be sent to the TM latches block 204. The fuse data 252 can include non-TM data used, e.g., to set default values for or to repair specific circuits on a chip. The fuse data 252 is stored and locally latched via fuse latching block 250. A fuse data signal 254 having the latched fuse data can be multiplexed by the multiplexer 110 and sent onto the lane 115. As shown in the illustrated embodiment, latched fuse data can also be sent via a fuse data signal 256 to TM latches block 204. In some embodiments, the latched fuse data can initialize latching of the TM bits prior to the TM signals 105, and be sent to its destination along a multiplexed path with the TM data. Once multiplexed, the fuse data signal 256 (or fuse data signal 254) can be demultiplexed or locally latched at its target destination in a manner similar to that described above for TM signals. As shown in the illustrated embodiments, the demultiplexed signal 258 can be routed to its target destination (e.g., on a relatively short local line from the demultiplexer to the target destination, rather than a space-consuming dedicated global line).

FIG. 3 is a simplified timing diagram schematically illustrating the operation of a memory device 300 (“device 300”) in accordance with embodiments of the present technology. As shown in the illustrated embodiment, the device 300 performs a first operation 302 in which multiple groups or phases having TM bits are sequentially sent, and a second operation 304 in which a single group or phase of TM bits is sent. The first operation 302 and the second operation 304 can be executed independent of one another, and are shown together in FIG. 3 for illustrative purposes. Referring to the first operation 302, the device 300 can begin operation by initiating a power or reset signal 305 (shown as “Power Up”), after which an initial fuse broadcast signal 315 (shown as “Fz Broadcast Enable”) is initiated. The fuse broadcast signal can be received by, e.g., the control block 202 (FIG. 2) and can ensure the fuse information has been locally latched by the fuse latches and is available for use prior to sending any TM data onto a lane. A fuse sending phase signal 350 (shown as “FzSend”) can be initiated after the fuse broadcast signal 315 is initiated, and can end after the fuse broadcast signal 315 ends. The fuse sending phase signal 350 can cause fuse information to be sent along one or more lanes 380 (shown as “tmfzLane”; referred to as “global lane 380”). As shown in the illustrated embodiment and indicated by the “<15:0>” designation in the global lane 380, the fuse information is sent to its target destination along a 16-bit wide bus.

Once the power signal 305 and the fuse broadcast signal 315, have been initiated, the device 300 for the first operation 302 can next initiate a TM broadcast signal 320 (shown as “TM Broadcast Enable”) to send TM keys or bits to their target destinations along the global lane 380. As described above, the TM broadcast signal 320 can clear the local latches by setting them to a known default state. Additionally, the TM broadcast signal 320 can also allow the individual local latches to be changed to the correct state for receiving TM data. In some embodiments, a TM enable signal 310 (shown as “TM Enable”) may be first initiated to enable the TM broadcast signal 320 to be sent. As shown in the illustrated embodiment, initiation of the TM broadcast signal 320 causes a first sending phase signal 325 (shown as imSendPh<0>″) to be initiated. Sending the first sending phase signal 325 causes the corresponding group or phase having TM data to be multiplexed and sent onto the global lane 380. As shown in the illustrated embodiment and indicated by the “<23:0>” designation in the global lane 380, the group corresponding to the first sending phase signal 325 includes 24 TM bits or keys. Once the first sending phase signal 325 is initiated, a first receiving phase signal 355 can then be initiated. As described above, the receiving phase signals are used to demultiplex the TM data being sent on the global lane 380. Initiating the receiving phase signal after initiating the corresponding sending phase signal can help ensure that each receiving phase signal corresponds to TM data already sent and/or multiplexed onto the global lane 380. As shown in the illustrated embodiment, the pulse width of the first receiving phase signal 355 is less than the pulse width of the sending phase signal 325. The pulse width of the sending phase signal should be long enough such that enough time is allowed for the TM data to pass through the multiplexer and onto the global lane 380. The pulse width of the receiving phase signal should be long enough to receive the incoming TM data at the local TM latches at the target destination. Delay logic can be used to define the pulse width of the sending phase signals and/or receiving phase signals.

Once the first sending phase signal 325 finishes (and closes), the global lane 380 becomes open for other groups or phases having TM data to be sent thereon. As such, subsequent sending phase signals and receiving phase signals can be initiated, in a similar manner to that described for the first sending phase signal 325 and the first receiving phase signal 355. For example, a second sending phase signal 330 (shown as “tmSendPh<1>”) can be initiated after the first sending phase signal 325 finishes, and initiation of the second sending phase signal 330 can thereby cause the second receiving phase signal 360 (shown as “tmReceivePh<1>”) to be initiated. As shown in the illustrated embodiment, a similar methodology is followed for the third sending phase signal 335 (shown as “tmSendPh<2>”) and the third receiving phase signal 365 (shown as “tmReceivePh<2>”), the fourth sending phase signal 340 (shown as “tmSendPh<3>”) and the fourth receiving phase signal 370 (shown as “tmReceivePh<3>”), and the fifth sending phase signal 345 (shown as “tmSendPh<4>”) and the fifth receiving phase signal 375 (shown as “tmReceivePh<4>”). For each pair of sending and receiving phase signals, (a) a group having TM data associated with the sending phase signal is multiplexed and sent along the global lane 380, (b) the receiving phase signal associated with that group is sent to demultiplex the TM data at its target destination, and then (c) the sending phase signal is closed. Once closed, the next pair of sending and receiving phase signals can be initiated and the next group having TM data can be sent onto the global lane 380. Once the last sending phase signal (e.g., the fifth sending phase signal 345 for the illustrated embodiment) closes, the TM broadcast signal 320 also closes, thereby allowing a new operation (e.g., another TM broadcast or a single TM load) to be initiated, In some embodiments, such as that shown in FIG. 3, closing of the last sending phase signal may initiate another sending phase signal (e.g., sending phase signal 325. This may be done to ensure the global lane 380 maintain a certain phase state and prevent the global lane 380 from falling into a floating state.

As described above, the device 300 can also perform a second operation 304 in which a single TM load is initiated to send a specific group of TM data to target destinations. This second operation 304 can begin when a TM load signal 385 (shown as “TM Load”) is initiated. The TM load signal 385 is a one-cycle command (e.g., not a broadcast signal) and includes an address for the TM key or bits that are to be enabled. Initiation or opening of the TM load signal can cause a sending phase signal to be initiated, thereby causing TM data associated with the group of that sending phase signal to be multiplexed onto the global lane 380 and sent to the target destinations of the corresponding TM data. As shown in the illustrated embodiment, for example, the first TM load signal 385a include a TM key or bits associated with the fourth sending phase signal 340. Initiation of the first TM load signal 385a causes the first sending phase signal 325 to close, thereby causing the fourth sending phase signal 340 to open. Opening of the fourth sending phase signal 340 can initiate the fourth receiving phase signal 370. The sending and receiving phase signals for the second operation 304 operate in a similar manner to that described above with respect to the first operation 302. One difference for the second operation 304, however, is that a sending phase signal for the second operation 304 may remain in an open state until a subsequent TM load signal is initiated. As noted above, this may be done to ensure the global lane 380 maintains a certain phase state (e.g., does not enter a floating state). As shown in the illustrated embodiment, for example, the fourth sending phase signal 340 remains open until a second TM load signal 385b is initiated, at which time the fourth sending phase signal 340 closes and the third sending phase signal 335 opens.

FIG. 4 is a flow chart illustrating a method 400 of operating a memory device (e.g., device 100, device 200 and/or device 300) or a system having the memory device in accordance with embodiments of the present technology. The method 400 can include assigning a plurality of test mode signals to a group (block 410). Each of the plurality of signals can include data related to TMs or fuses, as described above. Assigning the plurality of signals to a particular group can be based on, for example, their target destination. Assigning the plurality of signals can include assigning an address to the plurality of signals.

The method 400 can further include time multiplexing the group of assigned signals onto a data transmission line (block 420). Multiplexing the group of assigned signals onto the data transmission line can occur via a multiplexer, and can be in response to the multiplexer receiving a sending phase signal. The sending phase signal can be sent from a data traffic control block and can include data corresponding to the group that a particular signal is assigned to, as well as the target destination of each assigned signal of the group. Once the sending phase signal is sent, and/or once the group of assigned signals is multiplexed onto the data transmission line, receiving phase signals corresponding to each individual signal of the group can be sent to the target destinations of the individual signals. Similar to the sending phase signal, the receiving phase signals can include data corresponding to the group that a particular signal is assigned to, as well as the target destination of the individual signal to which the receiving phase signal corresponds. Once the individual target destination receives the corresponding receiving phase signal (block 430), that signal can be demultiplexed (e.g., latched) and the data (e.g., TM data and/or fuse data) can be executed.

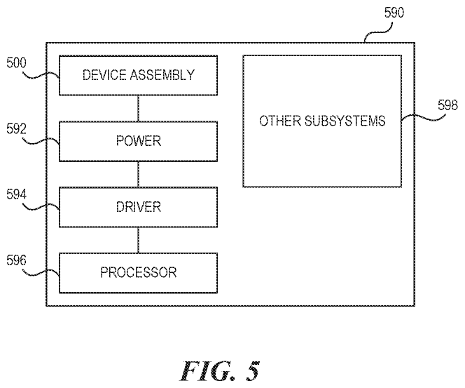

FIG. 5 is a schematic view of a system that includes a memory device in accordance with embodiments of the present technology. Any one of the foregoing memory devices described above with reference to FIGS. 1-4 can be incorporated into any of a myriad of larger and/or more complex systems, a representative example of which is system 590 shown schematically in FIG. 5. The system 590 can include a semiconductor device assembly 500, a power source 592, a driver 594, a processor 596, and/or other subsystems and components 598. The semiconductor device assembly 500 can include features generally similar to those of the memory devices described above with reference to FIGS. 1-4, and can, therefore, include various features of memory content authentication. The resulting system 590 can perform any of a wide variety of functions, such as memory storage, data processing, and/or other suitable functions. Accordingly, representative systems 590 can include, without limitation, hand-held devices (e.g., mobile phones, tablets, digital readers, and digital audio players), computers, vehicles, appliances, and other products. Components of the system 590 may be housed in a single unit or distributed over multiple, interconnected units (e.g., through a communications network). The components of the system 590 can also include remote devices and any of a wide variety of computer readable media.

The above detailed descriptions of embodiments of the technology are not intended to be exhaustive or to limit the technology to the precise form disclosed above. Although specific embodiments of, and examples for, the technology are described above for illustrative purposes, various equivalent modifications are possible within the scope of the technology as those of ordinary skill in the relevant art will recognize. For example, although steps are presented in a given order, alternative embodiments may perform steps in a different order. The various embodiments described herein may also be combined to provide further embodiments. Furthermore, the above detailed descriptions of embodiments of the technology are also not intended to limit the technology to the precise application disclosed above. Instead, various components and/or functions of the technology can be implemented in other applications. For example, while embodiments of the present technology are generally described with reference to memory devices, the present technology can also be used for a number of other applications, such as those devices using metal routing of signals to distribute large amounts of information (e.g., information other than TM data).

From the foregoing, it will be appreciated that specific embodiments of the technology have been described herein for purposes of illustration, but well-known structures and functions have not been shown or described in detail to avoid unnecessarily obscuring the description of the embodiments of the technology. Where the context permits, singular or plural terms may also include the plural or singular term, respectively. Moreover, unless the word “or” is expressly limited to mean only a single item exclusive from the other items in reference to a list of two or more items, then the use of “or” in such a list is to be interpreted as including (a) any single item in the list, (b) all of the items in the list, or (c) any combination of the items in the list. Additionally, the terms “comprising,” “including,” “having,” and “with” are used throughout to mean including at least the recited feature(s) such that any greater number of the same feature and/or additional types of other features are not precluded.

From the foregoing, it will also be appreciated that various modifications may be made without deviating from the disclosure. For example, one of ordinary skill in the art will understand that various components of the technology can be further divided into subcomponents, or that various components and functions of the technology may be combined and integrated. In addition, certain aspects of the technology described in the context of particular embodiments may also be combined or eliminated in other embodiments. Furthermore, although advantages associated with certain embodiments of the new technology have been described in the context of those embodiments, other embodiments may also exhibit such advantages and not all embodiments need necessarily exhibit such advantages to fall within the scope of the technology. Accordingly, the disclosure and associated technology can encompass other embodiments not expressly shown or described.

1. A method for operating a semiconductor device, the method comprising:
assigning a plurality of test mode signals to a group, the plurality of test mode signals including a first test mode signal designated to be received at a target destination that is separate from a second target destination;
multiplexing the group of assigned test mode signals onto a data transmission line corresponding to a single lane electrically connecting two points, wherein the data transmission line is directly connected to the target destination and the second target destination;
receiving a phase signal at the target destination of the first test mode signal; and
demultiplexing the first test mode signal at the target destination, based at least partially on the received phase signal.

2. The method of claim 1 wherein each of the test mode signals includes fuse data.

3. The method of claim 1 wherein the phase signal is a receiving phase signal including data corresponding to the target destination, and wherein multiplexing the assigned test mode signals occurs via a multiplexer, the method further comprising providing a sending phase signal to the multiplexer, the sending phase signal including the data corresponding to the target destination.

4. The method of claim 3 wherein receiving the receiving phase signal occurs after sending the sending phase signal.

5. The method of claim 1 wherein the phase signal is a first phase signal, the target destination is a first target destination, and the plurality of test mode signals includes a second test mode signal, the method further comprising:
receiving a second phase signal at the second target destination of the second test mode signal, the second target destination being different than the first target destination; and
demultiplexing the second test mode signal at the second target destination based on the received second phase signal.

6. The method of claim 1 wherein assigning the plurality of test mode signals is based on the target destinations of the plurality of test mode signals.

7. The method of claim 1 wherein the data transmission line is one or a plurality of data transmission lines defining a data transmission bus width.

8. The method of claim 1 wherein assigning the plurality of test mode signals to the group includes assigning an address to each of the plurality of test mode signals, wherein each address includes information of the target destination of the corresponding individual test mode signal.

9. The method of claim 1 wherein the group is one of a plurality of groups and the data transmission line is one of a plurality of data transmission lines, and wherein the phase signal includes data corresponding to (a) the group to which the plurality of test mode signals is assigned, and (b) the data transmission line onto which the assigned test mode signals are multiplexed.

10. The method of claim 1 wherein the plurality of test mode signals is a first plurality of test mode signals, the group is a first group, the phase signal is a first phase signal, and the target destination is a first target destination, the method further comprising:
assigning a second plurality of test mode signals to a second group, the second plurality of test mode signals including a second test mode signal;
multiplexing the second group of assigned test mode signals onto the data transmission line after multiplexing the first group of assigned test mode signals onto the data transmission line;
receiving a second phase signal at +the second target destination of the second test mode signal; and
demultiplexing the second test mode signal at the second target destination based on the received second phase signal.

11. The method of claim 1 wherein the semiconductor device is a dynamic random access memory device.

12. A memory device, comprising:
a data transmission line corresponding to a single lane electrically connecting two points;
a multiplexer in communication with the data transmission line and configured to multiplex a group of test mode signals onto the data transmission line;
a plurality of demultiplexers directly connected to the data transmission line, each demultiplexer being configured to demultiplex multiplexed test mode signals at individual target destinations of the signals; and
control logic configured to
assign the test mode signals to the group,
send a first phase signal to the multiplexer, causing the multiplexer to multiplex the group of test mode signals onto the data transmission line, and
send a plurality of second phase signals to corresponding demultiplexers, causing the demultiplexers to demultiplex individual multiplexed test mode signals at corresponding target destinations.

13. The memory device of claim 12 wherein individual demultiplexers are latches at the corresponding target destinations.

14. The memory device of claim 12 wherein the first phase signal is a sending phase signal including information corresponding to (a) the group the test mode signals are assigned to and (b) the data transmission line the group is multiplexed onto.

15. The memory device of claim 12 wherein the second phase signals are receiving phase signals sent to target destinations of individual test mode signals, each of the receiving phase signals including information corresponding to (a) the group the test mode signals are assigned to and (b) the data transmission line the group is multiplexed onto.

16. The memory device of claim 12 wherein the demultiplexers are latches and the second phase signals include a first receiving phase signal and a second receiving phase signal, and wherein causing the demultiplexers to demultiplex individual multiplexed test mode signals at corresponding target destinations includes:
causing a first local latch to demultiplex a first multiplexed test mode signal at a first target destination, based on the first receiving phase signal received at the first local latch; and
causing a second local latch to demultiplex a second multiplexed test mode signal at a second target destination, based on the second receiving phase signal received at the second local latch, the second target destination being different than the first target destination.

17. The memory device of claim 12 wherein each of the test mode signals includes fuse data.

18. A method for operating a memory device, the method comprising:
time multiplexing a group of test mode signals onto one of a plurality of data transmission lines, wherein the one of the plurality of the data transmission lines corresponds to a single lane electrically connecting two points;
providing receiving phase signals to target destinations of each of the plurality of test mode signals; and
demultiplexing individual multiplexed signals based on the receiving phase signals, wherein demultiplexing includes receiving each test mode signal at a corresponding target destination directly from the one of the plurality of the data transmission lines.

19. The method of claim 18 wherein demultiplexing individual multiplexed signals occurs via local latches, the method further comprising, before demultiplexing the individual multiplexed signals at the corresponding target destinations, routing individual multiplexed signals from the one of the data transmission lines to the local latches to be demultiplexed.

20. The method of claim 18, further comprising, prior to demultiplexing the group, assigning the test mode signals to the group based at least in part on the target destinations of the test mode signals.

21. The method of claim 18 wherein multiplexing the group occurs via a multiplexer, the method further comprising providing a sending phase signal to the multiplexer, the sending phase signal including data corresponding to the group the plurality of test mode signals are assigned to, and (b) the target destinations of each of the plurality of test mode signals.

22. The method of claim 18 wherein each of the phase signals includes data corresponding to the group, the data transmission line, and the corresponding target destination.

23. The method of claim 18 wherein demultiplexing individual multiplexed signals occurs via local latches, the method further comprising, before demultiplexing the individual multiplexed signals at the corresponding target destinations, sending a clearing signal configured to set one or more of the local latches to a default state.
